(19) United States
(12) Patent Application Publication
(10) Pub. No.: US 2006/0198205 A1
(43) Pub. Date: Sep. 7, 2006

(54) User-Configurable Pre-Recorded Memory and System

(76) Inventor: Guobiao Zhang, Stateline, NV (US)

Correspondence Address: Dr.Guobiao Zhang, P.O. Box 6182, Stateline, NV, 89449-6182, US

(21) Appl. No.: 11/306,691

(22) Filed: Jan. 6, 2006

Related U.S. Application Data
(63) Continuation-in-part of application No. 11/164,246, filed on Nov. 15, 2005.
Application No. 11/164,246 is a continuation-in-part of application No. 11/036,448, filed on Jan. 15, 2005.

(51) Int. Cl. G11C 7/10

(52) U.S. Cl. 365/189.01

(57) ABSTRACT

In a user-configurable pre-recorded memory (UC-PM), a user may configure his accessibility and only pays the associated access fee. A UC-PM preferably comprises a pre-recorded memory and an access-control circuit. To protect copyright, pre-recorded contents are preferably encrypted. A UC-PM system offers excellent access control and impenetrable copyright protection. The UC-PM will enable a content-distribution model fair to both copyright holders and users.

### CROSS-REFERENCE TO RELATED APPLICATIONS

This application is a continuation-in-part of U.S. patent application Ser. No. 11/164,246, filed Nov. 15, 2005, which is a continuation-in-part of U.S. patent application Ser. No. 11/036,448, filed Jan. 15, 2005, which is related to U.S. Provisional Application No. 60/559,683, filed Apr. 4, 2004 and Chinese P.R. patent application No. 200410081241.X, filed Nov. 15, 2004. This application is also related to U.S. Provisional Application No. 60/740,373, filed Nov. 28, 2005, all by the same inventor.

### BACKGROUND

1. Technical Field of the Invention

The present invention relates to the field of storage system, and more particularly to pre-recorded memory.

2. Related Arts

Pre-recorded memory (PM) refers to memory whose contents are written before reaching a user's hand. It relieves user of the burden of downloading contents and therefore, provides great convenience. PM is suitable for publishing, particularly for publishing copyrighted contents, e.g. multimedia data, electronic books/dictionaries/maps, electronic games and software.

The prior-art PM has a small capacity. It can hold just a small number of pre-recorded files. As illustrated in FIG. 1A, PM 14d can hold one file 12d. In order to satisfy the user needs 10 (e.g. including files 12a, 12d, 12e), a large number of PM's are required (e.g. 14a, 14d, 14e).

As illustrated in FIG. 1B, with the advancement of memory technology, the PM capacity 20 increases dramatically. In contrast, the user needs 10 increase at a slower rate (thanks to the more efficient compression techniques). As a result, at point A, one or a small number of PM's can satisfy the user needs 10.

As illustrated in FIG. 1C, with further technology advance, the PM capacity 20 become so large that it can not only satisfy the needs from an individual user, but also satisfy most needs for general users (after point A of FIG. 1B). With such a large amount of contents stored in the PM 16, the associated copyright fees would be huge. If unlimited access is granted, this PM 16 would be too expensive to be afforded by an average user. In fact, a user may just want limited access to certain contents. Accordingly, the present invention discloses a user-configurable pre-recorded memory (UC-PM). In a UC-PM, a user may configure his accessibility (i.e. the extent he can access contents) and only pays the associated access fee.

### OBJECTS AND ADVANTAGES

It is a principle object of the present invention to provide a pre-recorded memory where a user can configure his accessibility, i.e. the extent he can access contents.

It is a further object of the present invention to provide a pre-recorded memory where a user only pays the access fee associated with his accessibility.

It is a further object of the present invention to provide a user-configurable pre-recorded memory with excellent copyright protection.

It is a further object of the present invention to provide a content-distribution model fair to both copyright holders and users.

In accordance with these and other objects of the present invention, a user-configurable pre-recorded memory (UC-PM) is disclosed.

### SUMMARY OF THE INVENTION

Pre-recorded memory (PM) is released to a user with pre-recorded contents. It relieves user of the burden of downloading contents and therefore, provides great convenience. PM could use any type of storage device, e.g. flash memory, mask-ROM. One memory of particular interest is three-dimensional memory (3D-M). 3D-M, more particularly three-dimensional mask-programmable memory (3D-MPM), has a small size, large capacity and low cost. It is suitable to store pre-recorded contents, particularly in a mobile environment.

The present invention discloses a user-configurable pre-recorded memory (UC-PM). In a UC-PM, a user may configure his accessibility (i.e. the extent a user can access contents) and only pays the associated access fee. Take a music UC-PM as an example. An as-sold music UC-PM provides little music access (e.g. a user can listen to a song or a section of song for several times as trial). After purchasing an access code from the copyright holder and entering it into the UC-PM, the user gains an appropriate accessibility, e.g. he can listen to a song or a number of songs for certain number of times.

A UC-PM preferably comprises a PM and an access-control circuit. The PM stores a plurality of pre-recorded files and the access-control circuit controls access to these files. The UC-PM could further comprise a decryption engine. In this case, the pre-recorded contents are encrypted. When access to a file is granted, the access-control circuit releases the key to said file to the decryption engine. Encrypted contents have a better data security, especially when the PM and the access-control circuit are physically separated (e.g. housed in different packages) and their data communication might be tampered with.

The present invention further discloses a UC-PM system. It comprises a content-storage means for storing pre-recorded contents and a content-playback means for generating user-perceptible signals (e.g. mechanical sound or optical images). To protect copyright, all UC-PM system components should be tamper-proof, i.e. they preferably take the form of a single chip, a single package, or a chip/package-on-a-panel (i.e. chip or package directly mounted on a display panel). Plaintext content signals can only flow Inside the tamper-proof component; all external content signals are preferably encrypted (for digital content signals), or non-digital electrical (e.g. analog, PWM, PPM), or non-electrical (e.g. mechanical sound, optical image) (referring to the co-pending U.S. patent application Ser. No. 10/906,609).

The present invention further discloses a hybrid memory. It comprises a PM and a user-memory. The PM stores the pre-recorded contents and the user-memory stores user file (e.g. downloaded contents). The user-memory preferably uses writable memory. If the PM uses writable memory, the PM and user-memory can share the same memory. To access pre-recorded contents, no download is needed; to access latest contents, the user may download and store them in the user-memory. The hybrid memory is both convenient and flexible.

The UC-PM will enable a new content-distribution model—UC-PM model. Because it can provide excellent access control and impenetrable copyright protection, a UC-PM (or system) can be obtained at a price much lower than its hardware cost (or simply free). As a user gains access to contents by paying the access fee, the hardware manufacturer can recoup a portion of the hardware cost from the access fee. The UC-PM model is fair to both copyright holders and users. It will facilitate broad acceptance of the UC-PM and its system.

### BRIEF DESCRIPTION OF THE DRAWINGS

FIG. 1A illustrates the relative sizes of the PM capacity and user needs in prior arts; FIG. 1B illustrates the relative growth trend of the PM capacity and user needs; FIG. 1C illustrates the relative sizes of the PM capacity and user needs for a UC-PM;

FIG. 2 illustrate a general UC-PM usage model;

FIG. 3A illustrates a first preferred UC-PM usage model; FIG. 3B illustrates a second preferred UC-PM usage model;

FIG. 4 is a block diagram of a first preferred UC-PM;

FIG. 5 illustrates a preferred PM;

FIG. 6 illustrates a preferred access-control circuit for the first preferred UC-PM;

FIGS. 7A-7B illustrate two preferred tag blocks;

FIG. 8 is a block diagram of a second preferred UC-PM;

FIG. 9 illustrates a preferred access-control circuit for the second preferred UC-PM;

FIG. 10A-10B illustrate two preferred key blocks;

FIGS. 11A-11C illustrate three preferred tag-configuration blocks;

FIGS. 12A-12C illustrate several preferred solid-state-memory-based UC-PM's;

FIG. 13 illustrates a preferred UC-PM system;

FIG. 14A-14D illustrate four preferred system partitions of a UC-PM system;

FIG. 15 illustrates a preferred hybrid memory;

FIG. 16 illustrates a preferred content-distribution model.

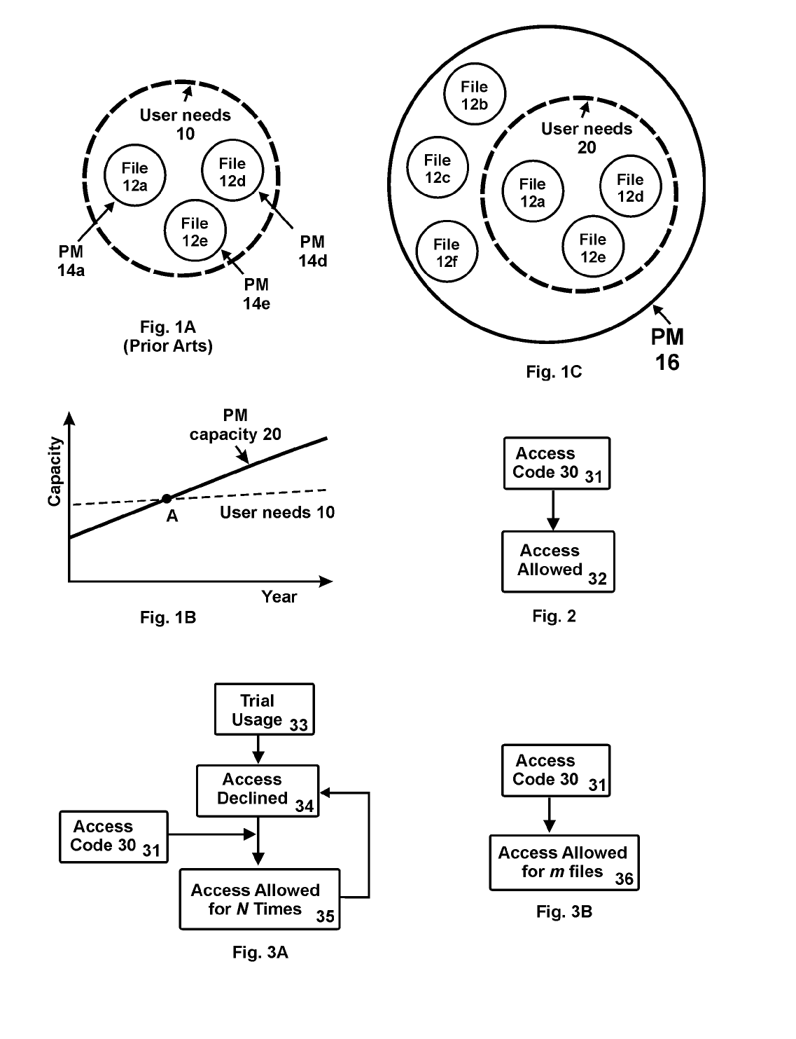

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention discloses a user-configurable pre-recorded memory (UC-PM). The as-sold UC-PM has limited access. A user may configure his accessibility (i.e. the extent he can access contents) by entering different access codes. As illustrated in FIG. 2, after an access code 30 is entered into the UC-PM (step 31), access is allowed to certain contents (step 32).

FIGS. 3A-3B illustrate two preferred UC-PM usage models. The UC-PM's in these figures are music PM's. In FIG. 3A, initially there is a trial period. During this period, a user is allowed to listen to each song for several times (or for a pre-determined time) as trial (step 33). After this period, no further access is allowed (step 34). Only after the access code 30 is entered into the UC-PM (step 31), the user is allowed to listen to the associated song for N times (N could be infinite) (step 35). In FIG. 3B, the access code 30 can enable access to m files. To be more specific, by entering a single access code 30 (step 31), the user can gain access to a total of m files (step 36). This usage model is convenient because the user does not have to enter an access code for each selected song.

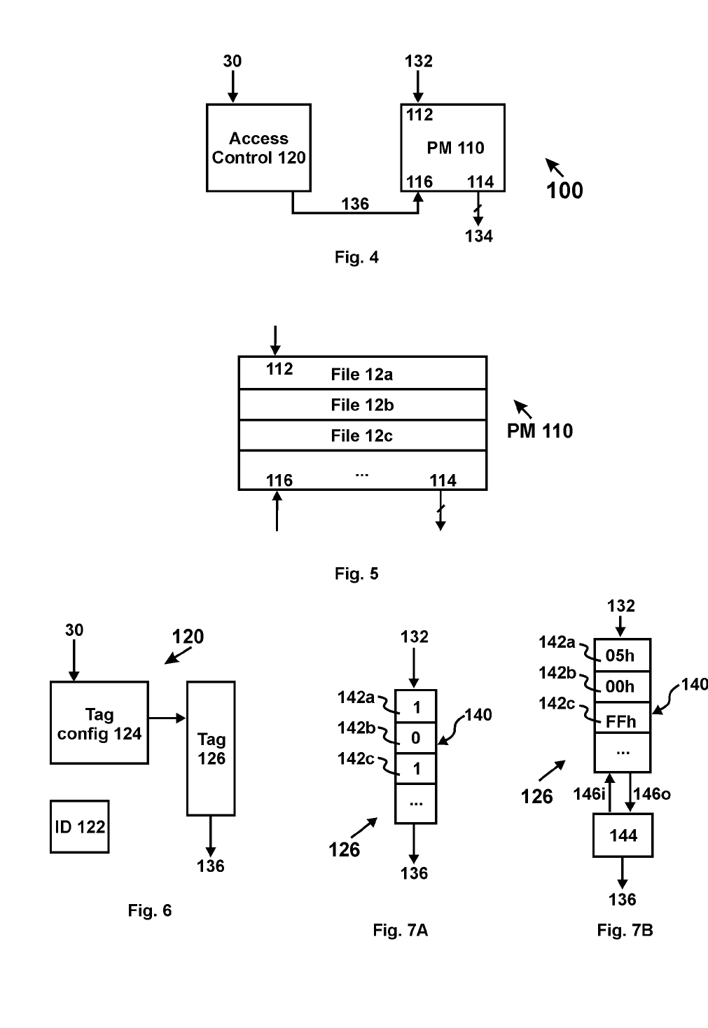

Referring now to FIG. 4, a first preferred UC-PM 100 is disclosed. It comprises a pre-recorded memory (PM) 110 and an access-control circuit 120. The PM 110 stores a plurality of pre-recorded files. It has an address port 112, output port 114 and a read-enable port 116. Using an appropriate address 132 and provided that the read-enable signal 136 is high, a user can select the file-of-interest 134. The access-control circuit 120 controls access to pre-recorded files. It contains their accessibility information, which can be changed by the access code 30. Further details on these blocks are disclosed in FIGS. 5-7B.

FIG. 5 illustrates a preferred PM 110. It stores a plurality of pre-recorded files (12a, 12b . . . ), which can be selected by address 132. PM 110 could use any type of storage device, e.g. flash memory, mask-ROM. One memory of particular interest is three-dimensional memory (3D-M). 3D-M, more particularly three-dimensional mask-programmable memory (3D-MPM), has a small size, large capacity and low cost. It is suitable to store pre-recorded contents, particularly in a mobile environment.

FIG. 6 illustrates a preferred access-control circuit 120 for the first preferred UC-PM 100 (FIG. 4). It controls access to the pre-recorded files through a read-enable signal 136. When 136 is high, access to the selected file is allowed (FIG. 4). The access-control circuit 120 comprises an ID 122, a tag block 126 and a tag-configuration block 124: the ID 122 is a unique number that can be used to identify the UC-PM 100; the tag block 126 contains the accessibility information; and the tag-configuration block 124 changes the accessibility information based on the access code 30.

FIGS. 7A-7B illustrate two preferred tag blocks 126. Both comprise a tag-array 140, which consists of a plurality of cells (142a, 142b . . . ). Each cell, indexed by address 132, contains the tag value for a pre-recorded file (e.g. 142a for file 12a, 142b for file 12b . . . ). In these two preferred embodiments, the tag value represents the accessibility information.

In FIG. 7A, each tag value has a single bit, i.e. it can be either “0” or “1”. If a tag value (e.g. 142a) is “1”, access to its associated file (e.g. 12a) is allowed; otherwise no access is allowed.

In FIG. 7B, each tag value has more than one bit and its value is equal to the number of remaining accesses. In this preferred embodiment, each tag value has 8 bits. For example, “05h” (in 142a) means there are 5 times of remaining accesses to file 12a; “00h” (in 142b) means there is no (0 times) access to file 12b; “FFh” (in 142c) means there is unlimited access to file 12c. The tag block 126 further comprises a tag-controller 144. It sets the read-enable signal 136 and updates the tag value for the addressed file: if 146o>“00h”, 136 is set to high; after each read, if “00h”<146o<“FFh”, 146o decreases by 1 (146i=146o−1) and is written back to the tag-array 140.

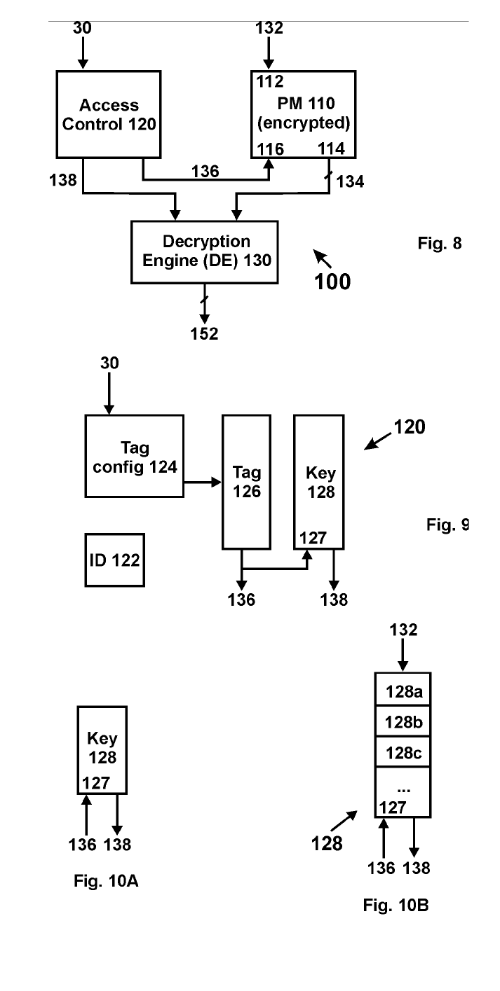

Referring now to FIG. 8, a second preferred UC-PM 100 is disclosed. It comprises a pre-recorded memory (PM) 110, an access-control circuit 120 and a decryption engine (DE) 130. Its pre-recorded contents are encrypted. When access to a file is granted, the access-control circuit 120 releases the key 138 to said file to the DE 130, which converts the encrypted output 134 into plaintext contents 152. Encrypted contents have a better data security, especially when the PM 110 and the access-control circuit 120 are physically separated (e.g. housed in different packages) and their data communication might be tampered with.

FIG. 9 illustrates a preferred access-control circuit 120 for the second preferred UC-PM 100 (FIG. 8). It is similar to the access-control circuit of FIG. 5, except for an additional key block 128. The key block 128 stores the key(s) to the encrypted contents. It has a read-enable port 127. If signal 136 is high, key 138 will be read out and released to the DE 130.

FIGS. 10A-10B illustrate two preferred key blocks. In FIG. 10A, a common key is used for all pre-recorded files. In FIG. 10B, the key block 128 comprises a plurality of keys (128a, 128b . . . ). Each key is associated with a file or a group of files (e.g. key 128a for file 12a, key 128b for file 12b . . . ). They are indexed by address 132.

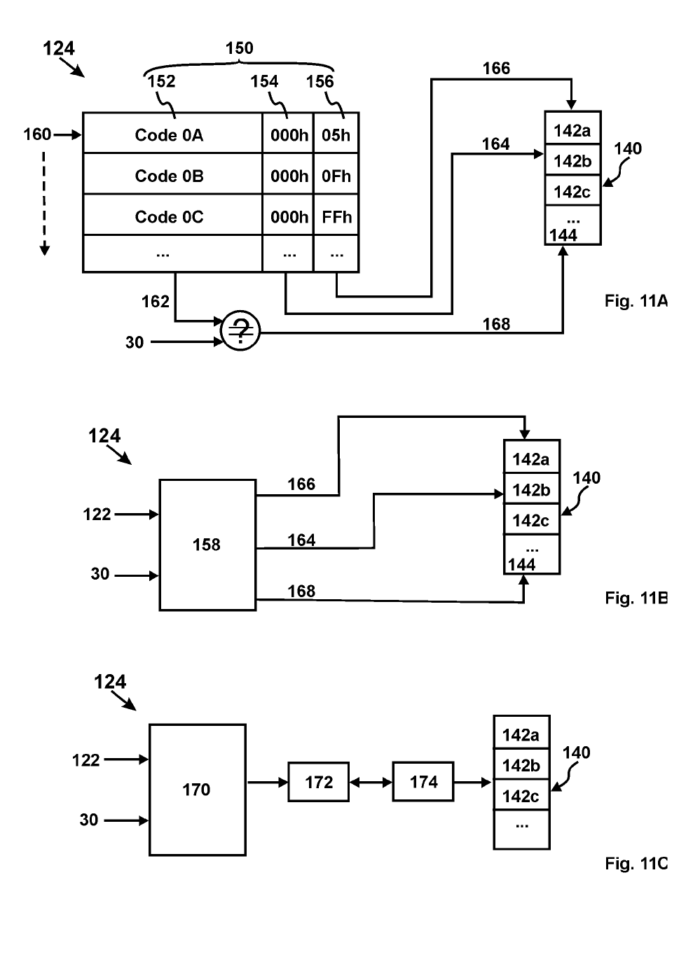

FIGS. 11A-11C illustrate three preferred tag-configuration blocks. Based on the access code 30, they can change the tag value (i.e. accessibility information) stored in the tag block 126. The preferred tag-configuration blocks in FIGS. 11A-11B can implement the usage model of FIG. 3A, and the preferred tag-configuration block in FIG. 11C can implement the usage model of FIG. 3B.

FIG. 11A illustrates a first preferred tag-configuration block 124. It comprises a look-up table, i.e. code-conversion table 150, which has a number of entries 160. Each entry 160 consists of an access code 152, file index 154 and access level 156 (e.g. desired number of accesses). For example, “Code 0A” means 5 times (“05h”) of accesses are allowed for the file 000h; “Code 0B” means 15 times (“0Fh”) of accesses are allowed for file 000h; “Code 0C” means unlimited (“FFh”) accesses are allowed for file 000h. During tag configuration, each entry 160 in the code-conversion table 150 is searched. If its output 162 matches the access code 30, signal 168 is set to high and sent to the write-enable port 144 of the tag-array 140. Using the file index 164 as address, the access level 166 can be written into the tag-array 140.

FIG. 11B illustrates a second preferred tag-configuration block 124. Instead of using a look-up table of FIG. 11A, it uses an ASIC-block 158 to implement the following functions:
File index 164=Function A (Access code 30, ID 122); Eq. (1)
Access level 166=Function B (Access code 30, ID 122). Eq. (2)
When the access code 30 is a valid code, signal 168 is set to high and sent to the write-enable port 144 of the tag-array 140. Similarly, using the file index 164 as address, the access level 166 can be written into the tag-array 140.

FIG. 11C illustrates a third preferred tag-configuration block 124. It can be used to implement the usage model of FIG. 3B, where the access code 30 can enable access to a total of m files. The tag-configuration block 124 comprises a code-converter 170, an access-register 172 and an access-controller 174. The access-register 172 stores the remaining number of files whose accesses are allowed. During tag configuration, the code-converter 170 initializes the access-register 172 to the m corresponding to the inputted access code 30 and ID 122. During content playback, when a user wants to access a new file, the access-controller 174 checks the access-register 172. If the value in the access-register 172 is >“00h”, the tag value of this file is set to high, while the value of the access-register 172 decreases by 1.

In FIGS. 4-11C, the values of ID 122, key block 128 and the code-conversion table 150 need to be set before the UC-PM reaches the user's hand. The tag block 126 of FIG. 7A needs to be set once by the user. They all (122, 128, 150, 126) can use one-time-programmable memory (OTP). Two OTP candidates are XPS memory from Kilopass Inc. (referring to U.S. Pat. No. 6,777,757) and three-dimensional electrically-programmable memory (3D-EPROM). On the other hand, the tag block 126 in FIG. 7B needs to use write-many-times memory (WM).

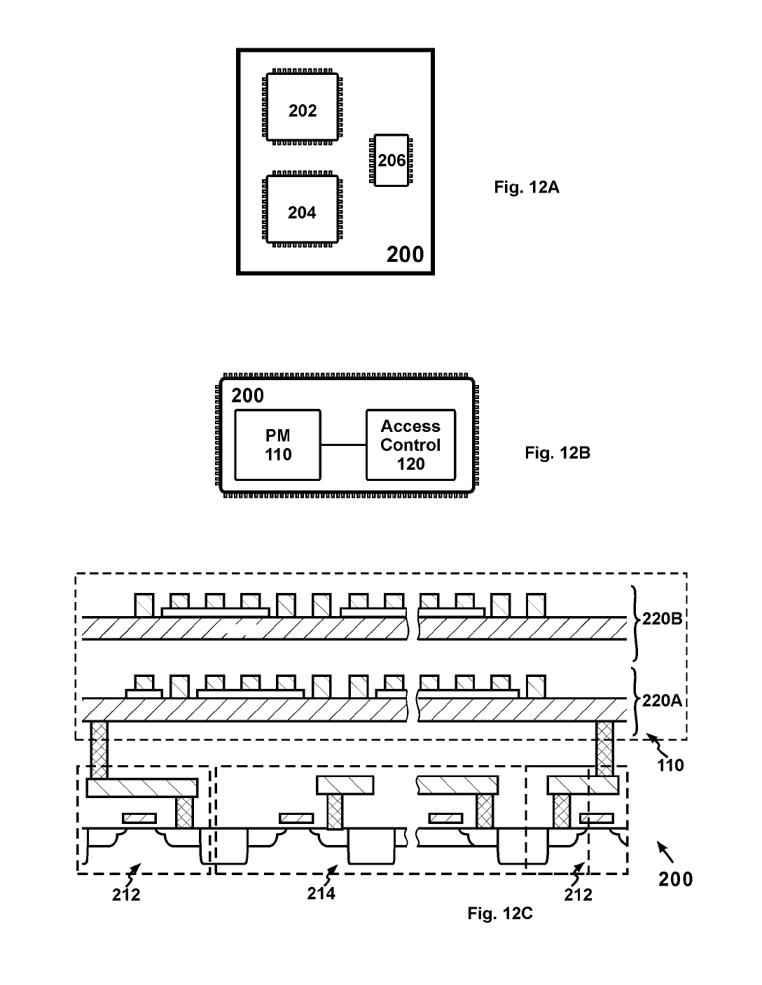

Referring now to FIGS. 12A-12C, several preferred solid-state-memory-based UC-PM's are disclosed. The solid-state memory could be any type of non-volatile memory, e.g. flash memory, mask-ROM, or other types of memory. It is particularly suitable for music release.

In FIG. 12A, the UC-PM 200 comprises two memory packages 202, 204 and an access-control package 206 (optionally with DE 130, for encrypted PM). The memory packages 202, 204 store pre-recorded contents. It could use any type of solid-state memory, e.g. flash memory, mask-ROM.

In FIG. 12B, the UC-PM 200 is in a single package or a single chip. It comprises the PM block 110 and the access-control block 120 (optionally with DE 130, for encrypted PM). Integrating into a single package or a single chip makes the UC-PM 200 less prone to tampering. Similarly, PM could use any type of solid-state memory, e.g. flash memory, mask-ROM.

Among all solid-state memories, three-dimensional memory (3D-M) has the largest capacity. For example, at the 0.1 μm node, the die size of a 1 GB three-dimensional mask-programmable memory (3D-MPM) could be as small as ˜40 mm². With a small size, large capacity and low cost, 3D-MPM is particularly suitable to store pre-recorded contents, especially music, in a mobile environment. In FIG. 12C, the PM 110 is a 3D-MPM. It comprises two memory levels 220A, 220A. Because 3D-MPM does not occupy substrate area (except for its decoder 212), the substrate area 214 can be used to build access-control circuit (optionally with DE 130, for encrypted PM) and other circuit blocks. Since 3D-MPM and the access-control circuit are integrated into a single chip, this preferred embodiment provides excellent access control.

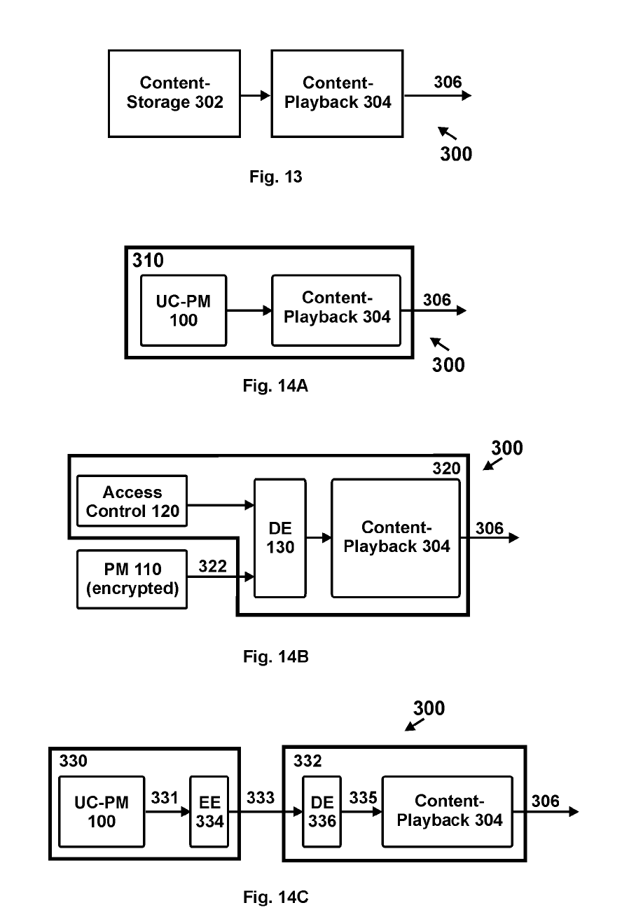

The present invention further discloses a UC-PM system. As illustrated in FIG. 13, a UC-PM system 300 comprises a content-storage means 302 for storing pre-recorded contents and a content-playback means 304 for generating user-perceptible signals (e.g. mechanical sound, optical image). The content-playback means 304 typically comprises a decoder and a data converter. The decoder decompresses the pre-recorded contents; the data converter generates user-perceptible signals 306. To protect copyright, all UC-PM system components should be tamper-proof, i.e. they preferably take the form of a single chip, a single package, or a chip/package-on-a-panel (i.e. chip or package directly mounted on a display panel). Plaintext content signals can only flow Inside the tamper-proof component; all external content signals are preferably encrypted (for digital content signals), or non-digital electrical (e.g. analog, PWM, PPM), or non-electrical (e.g. mechanical sound, optical image) (referring to the co-pending U.S. patent application Ser. No. 10/906,609).

FIGS. 14A-14D illustrate four preferred system partitions of a UC-PM system 300. The preferred embodiments in FIGS. 14A-14B comprise one tamper-proof component; on the other hand, the preferred embodiments in FIGS. 14C-14D comprise two tamper-proof components.

In FIG. 14A, the UC-PM 100 and content-playback means 304 are integrated into a single tamper-proof component 310. Because no content signals are exposed, the pre-recorded contents can be either encrypted or plaintext.

In FIG. 14B, the PM 110 is a standalone memory and its contents are encrypted. The access-control circuit 120, DE 130 and content-playback means 304 are integrated into a tamper-proof component 320. Because the pre-recorded contents stored in PM 110 are encrypted, data communication 322 between PM 110 and system component 320 is secure.

In FIG. 14C, the preferred UC-PM system 300 further comprises an encryption engine (EE) 334 and a decryption engine (DE) 336. Its UC-PM 100 and EE 334 are integrated into a first tamper-proof component 330, while the DE 336 and content-playback means 304 are integrated into a second tamper-proof component 332. During content playback, EE 334 converts the plaintext contents 331 from the UC-PM 100 into encrypted form 333, while DE 336 converts it back to plaintext form 335. Because content signals 333 are encrypted, data communication between system components 330, 332 is secure.

In FIG. 14D, the preferred UC-PM system 300 further comprises an encryption engine (EE) 344 and a decryption engine (DE) 346. Its PM 110 is a standalone memory and its contents are encrypted. The access-control circuit 120 and EE 344 are integrated into a first tamper-proof component 340; and two DE's (346, 130) and content-playback means 304 are integrated into a second tamper-proof component 342. During content playback, EE 344 converts the key 138 into encrypted form 341 and DE 246 converts it back into plaintext form 343, then DE 130 decrypts the encrypted contents 134 using the plaintext key 343. Because content signals 134 and key 341 are both encrypted, data communications between all system components are secure. Note that EE's 346, 130 can share one decryption engine.

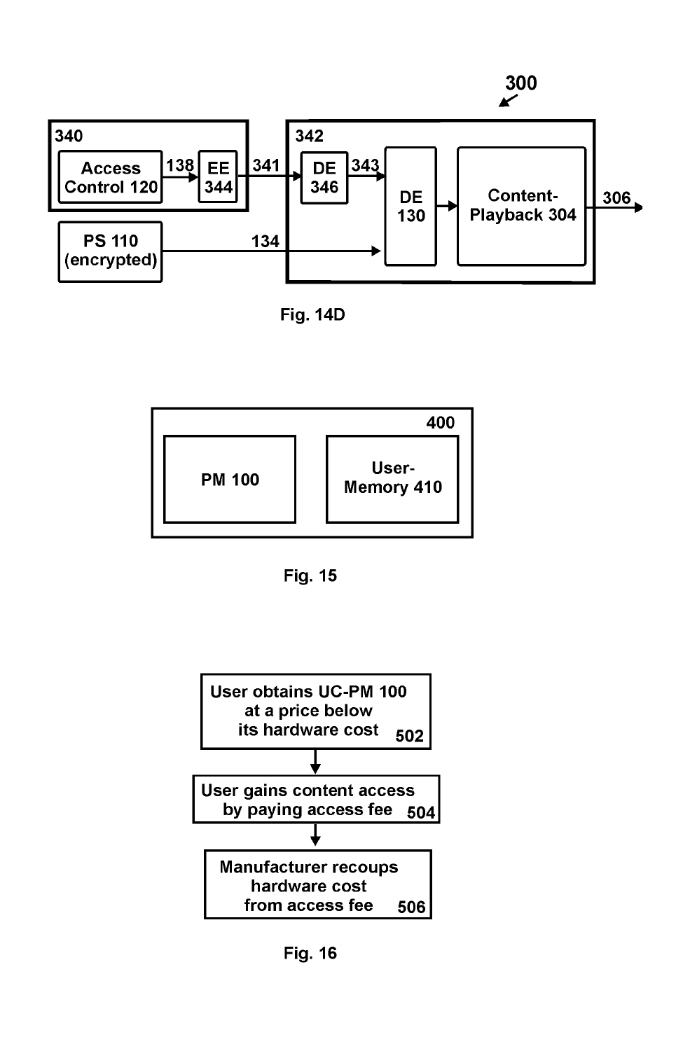

The present invention further discloses a hybrid memory. As illustrated in FIG. 15, the hybrid memory 400 comprises a PM 100 and a user-memory 410. The PM 100 stores the pre-recorded contents and the user-memory 410 stores user file (e.g. downloaded contents). The user-memory 410 preferably uses writable memory. In case the PM 100 uses writable memory, the PM 100 and user-memory 410 can share the same memory. To access pre-recorded contents, no download is needed; to access latest contents, the user may download and store them in the user-memory 410. The hybrid memory 400 is both convenient and flexible.

The present invention further discloses a content-distribution model—UC-PM model. As illustrated in FIG. 16, a user can obtain a UC-PM 100 (or a UC-PM system 300) at a price much lower than its hardware cost (or simply free) (step 502). This is because UC-PM (or system) provides excellent access control and impenetrable copyright protection; furthermore, the hardware cost is far less than the copyright fees. After the user pays an access fee, an access code is sent to the user. After the access code is entered into the UC-PM 100, the user gains access to certain contents (step 504). In the meantime, the hardware manufacturer recoups a portion of the hardware cost from the access fee (step 506). The UC-PM model is fair to both copyright holders and users. It will facilitate broad acceptance of the UC-PM and its system.

While illustrative embodiments have been shown and described, it would be apparent to those skilled in the art that may more modifications than that have been mentioned above are possible without departing from the inventive concepts set forth therein. For example, the preferred PM's disclosed in FIGS. 12A-12C are solid-state memory. In fact, PM may use any type of mass-storage device, e.g. mass-storage using magnetic means or optical means (referring to the co-pending U.S. Patent Application No. 60/740,373). The invention, therefore, is not to be limited except in the spirit of the appended claims.

What is claimed is:

1. A user-configurable pre-recorded memory (UC-PM), comprising:
a memory for storing a plurality of pre-recorded files; and
an access-control means for controlling access to selected ones of said pre-recorded files.

2. The UC-PM according to claim 1, wherein said memory is a solid-state memory.

3. The UC-PM according to claim 2, wherein said solid-state memory is a flash memory or mask-ROM.

4. The UC-PM according to claim 2, wherein said solid-state memory is a three-dimensional memory.

5. The UC-PM according to claim 4, wherein said solid-state memory is a three-dimensional mask-programmable memory.

6. The UC-PM according to claim 1, wherein said access-control means further comprise an ID for uniquely identifying said UC-PM.

7. The UC-PM according to claim 1, wherein said access-control means further comprises a tag block having tag values for said pre-recorded files.

8. The UC-PM according to claim 7, wherein said access-control means further comprises a tag-configuration block for configuring said tag block.

9. The UC-PM according to claim 1, wherein:
said pre-recorded files are encrypted; and
said UC-PM further comprises a decryption means for decrypting said encrypted pre-record files.

10. The UC-PM according to claim 9, wherein said access-control means further comprises a key block for storing keys for said encrypted pre-recorded files.

11. The UC-PM according to claim 1, further comprising a user-memory.

12. A UC-PM system, comprising:
a memory for storing a plurality of pre-recorded files;
an access-control means for controlling access to selected ones of said pre-recorded files; and
a content-playback means for generating content outputs.

13. The UC-PM system according to claim 12, wherein said content outputs are non-digital electrical or non-electrical signals.

14. The UC-PM system according to claim 12, comprising at least a tamper-proof component.

15. The UC-PM system according to claim 14, wherein said tamper-proof component is a single chip, a single package, or a chip/package-on-panel.

16. The UC-PM system according to claim 14, wherein said tamper-proof component comprises said memory, said access-control means and said content-playback means.

17. The UC-PM system according to claim 12, wherein:
said pre-recorded files are encrypted; and
said UC-PM system further comprises a decryption means for decrypting said encrypted pre-record files.

18. The UC-PM system according to claim 17, further comprising at least a tamper-proof component.

19. The UC-PM system according to claim 18, wherein said tamper-proof component comprises one of the followings:
1) said access-control means, said decryption means and said content-playback means;
2) said access-control means and an encryption means for encrypting key; or
3) said decryption means and said content-playback means.

20. A content-distribution method, comprising the steps of:
1) a user obtaining a UC-PM at a price lower than the hardware cost, said UC-PM comprising a plurality of pre-recorded files;
2) said user gaining access to selected ones of said pre-recorded files by paying an access fee; and
3) the UC-PM manufacturer recouping at least a portion of the hardware cost from said access fee.
